(19) United States
(12) Patent Application Publication
(10) Pub. No.: US 2023/0146012 A1
(43) Pub. Date: May 11, 2023

(54) SEMICONDUCTOR MEMORY DEVICE AND METHOD OF FABRICATING THE SAME

(71) Applicant: Samsung Electronics Co., Ltd., Suwon-si (KR)

(72) Inventors: HYEON-WOO JANG, Hwaseong-si (KR); DONG-WAN KIM, Hwaseong-si (KR); Keonhee PARK, Suwon-si (KR); DONG-SIK PARK, Suwon-si (KR); SOOHO SHIN, Hwaseong-si (KP); JIHOON CHANG, Yongin-si (KR)

(21) Appl. No.: 17/954,394

(22) Filed: Sep. 28, 2022

(30) Foreign Application Priority Data
Nov. 5, 2021 (KR) 10-2021-0151646

(51) Int. Cl. H01L 27/108; G11C 5/06

(52) U.S. Cl. CPC H01L 27/10814; G11C 5/063; H01L 27/10823; H01L 27/10897

(57) ABSTRACT

Disclosed are semiconductor memory devices and their fabrication methods. The semiconductor memory device comprises a semiconductor substrate that includes a cell array region and a peripheral region, a plurality of bottom electrodes on the semiconductor substrate on the cell array region, a dielectric layer that conformally covers sidewalls and top surfaces of the bottom electrodes, and a top electrode on the dielectric layer and between the bottom electrodes. The top electrode includes a first metal layer, a silicon-germanium layer, a second metal layer, and a silicon layer that are sequentially stacked. An amount of boron in the silicon-germanium layer is greater than an amount of boron in the silicon layer.

### CROSS-REFERENCE TO RELATED APPLICATION

This U.S. nonprovisional application claims priority under 35 U.S.C §119 to Korean Patent Application No. 10-2021-0151646 filed on Nov. 5, 2021 in the Korean Intellectual Property Office, the disclosure of which is hereby incorporated by reference in its entirety.

### BACKGROUND

The present inventive concepts relate to a semiconductor memory device and a method of fabricating the same.

Semiconductor memory devices are beneficial in the electronic industry because of their small size, multi-functionality, and/or low fabrication cost. However, the semiconductor memory devices are being highly integrated with the remarkable development of the electronic industry. Line widths of patterns of the semiconductor memory devices are being reduced for high integration of the semiconductor memory devices. However, new exposure techniques and/or expensive exposure techniques are required for fineness of the patterns such that it is difficult to highly integrate semiconductor memory devices. Various studies have thus recently been conducted for new integration techniques. For example, research is being conducted to bury word lines inside a semiconductor substrate in DRAM memory devices.

### SUMMARY

Some embodiments of the present inventive concepts provide a semiconductor memory device with increased reliability.

Some embodiments of the present inventive concepts provide a method of fabricating a semiconductor memory device, which method is capable of preventing process defects and increasing a yield.

According to some embodiments of the present inventive concepts, a semiconductor memory device may comprise: a semiconductor substrate that includes a cell array region and a peripheral region; a plurality of bottom electrodes on the semiconductor substrate on the cell array region; a dielectric layer that conformally covers sidewalls and top surfaces of the bottom electrodes; and a top electrode on the dielectric layer and between the bottom electrodes. The top electrode may include a first metal layer, a silicon-germanium layer, a second metal layer, and a silicon layer that are sequentially stacked. An amount of boron in the silicon-germanium layer may be greater than an amount of boron in the silicon layer.

According to some embodiments of the present inventive concepts, a semiconductor memory device may comprise: a semiconductor substrate that includes a cell array region and a peripheral region; a plurality of bottom electrodes on the semiconductor substrate on the cell array region; a dielectric layer that conformally covers sidewalls and top surfaces of the bottom electrodes; and a top electrode on the dielectric layer and between the bottom electrodes. The top electrode may include a first metal layer, a silicon-germanium layer, a conductive adhesion layer, a second metal layer, and a silicon layer that are sequentially stacked.

According to some embodiments of the present inventive concepts, a semiconductor memory device may comprise: a semiconductor substrate that includes a cell array region and a peripheral region; a word line in the semiconductor substrate on the cell array region; a first impurity region in the semiconductor substrate on one side of the word line; a second impurity region in the semiconductor substrate on another side of the word line; a bit line on the semiconductor substrate on the cell array region and connected to the first impurity region, the bit line crossing over the word line; a bottom electrode on the semiconductor substrate on the cell array region and connected to the second impurity region; a dielectric layer that conformally covers a sidewall and a top surface of the bottom electrode; and a top electrode on the dielectric layer. The top electrode may include a first metal layer, a silicon-germanium layer, a second metal layer, and a silicon layer that are sequentially stacked. A surface roughness at a top surface of the silicon layer may be equal to or less than about 10 nm root mean square (RMS). A surface roughness at a lateral surface of the silicon layer may be greater than about 10 nm root mean square (RMS) and equal to or less than about 1,000 nm root mean square (RMS).

According to some embodiments of the present inventive concepts, a method of fabricating a semiconductor memory device may comprise: providing a semiconductor substrate that includes a cell array region and a peripheral region; forming a plurality of bottom electrodes on the semiconductor substrate on the cell array region; forming a dielectric layer that conformally covers sidewalls and top surfaces of the bottom electrodes; sequentially stacking a first metal layer, a silicon-germanium layer, a second metal layer, and a silicon layer on the dielectric layer; forming a first interlayer dielectric layer on the silicon layer; and removing a portion of the first interlayer dielectric layer by a polishing process to expose the silicon layer.

According to some embodiments of the present inventive concepts, a method of fabricating a semiconductor memory device may comprise: providing a semiconductor substrate that includes a cell array region and a peripheral region; forming a plurality of bottom electrodes on the semiconductor substrate on the cell array region; forming a dielectric layer that conformally covers sidewalls and top surfaces of the bottom electrodes; sequentially stacking a first metal layer and a silicon-germanium layer on the dielectric layer; removing the silicon-germanium layer and the first metal layer from the peripheral region; forming a first interlayer dielectric layer on the silicon-germanium layer; exposing the silicon germanium layer by removing a portion of the first interlayer dielectric layer with a polishing process; and sequentially stacking a second metal layer and a silicon layer on the silicon-germanium layer.

### BRIEF DESCRIPTION OF THE DRAWINGS

FIG. 1 illustrates a plan view showing a semiconductor memory device according to some embodiments of the present inventive concepts.

FIG. 2 illustrates a cross-sectional view taken along lines K-K′ and J-J′ of FIG. 1.

FIG. 3 illustrates a cross-sectional view taken along line M-M′ of FIG. 1.

FIGS. 4A to 4C illustrate cross-sectional views showing a method of fabricating the semiconductor memory device of FIG. 3.

FIG. 5 illustrates a cross-sectional view taken along line M-M′ of FIG. 1.

FIG. 6 illustrates a cross-sectional view taken along line M-M′ of FIG. 1.

FIG. 7 illustrates a cross-sectional view taken along line M-M′ of FIG. 1.

FIG. 8 illustrates a cross-sectional view showing a method of fabricating the semiconductor memory device of FIG. 7.

FIG. 9 illustrates a cross-sectional view taken along line M-M′ of FIG. 1.

FIGS. 10A to 10C illustrate cross-sectional views showing a method of fabricating the semiconductor memory device of FIG. 9.

### DETAILED DESCRIPTION OF EMBODIMENTS

Some embodiments of the present inventive concepts will now be described in detail with reference to the accompanying drawings to aid in clearly explaining the present inventive concepts. In this description, such terms as “first” and “second” may be used to simply distinguish identical or similar components from each other, and the sequence of such terms may be changed in accordance with the order of mention. In certain embodiments, the term “layer” may be replaced or interchangeable with “pattern”.

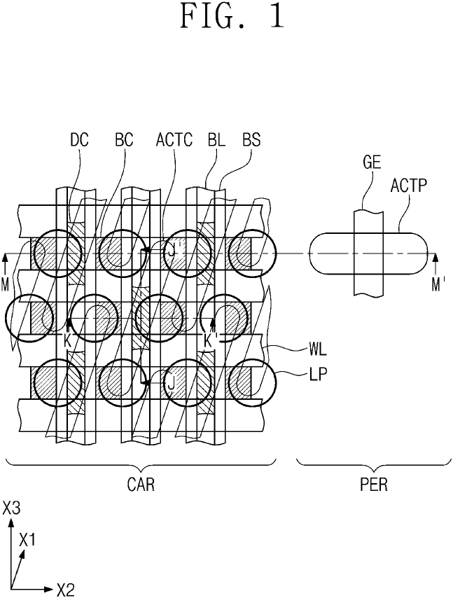

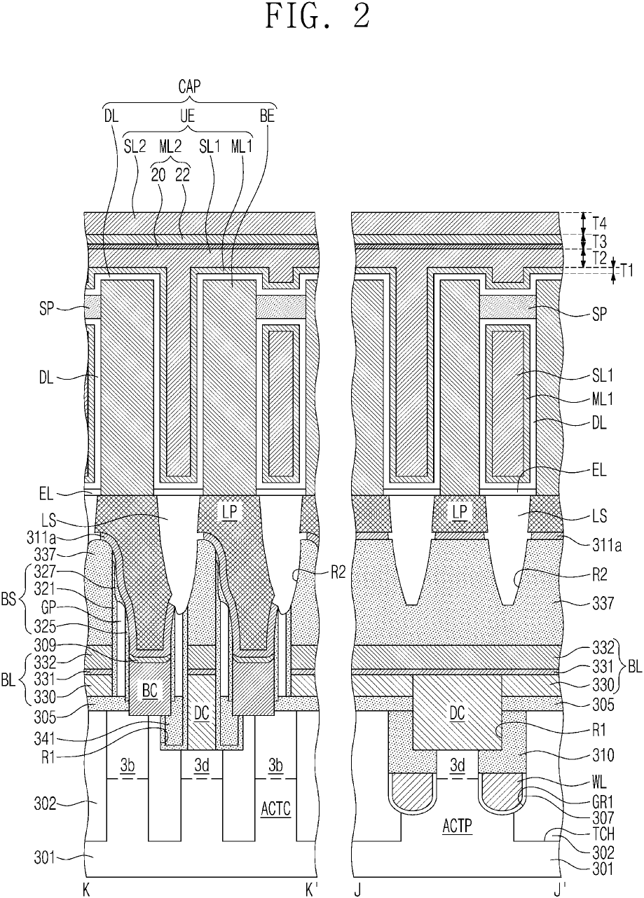

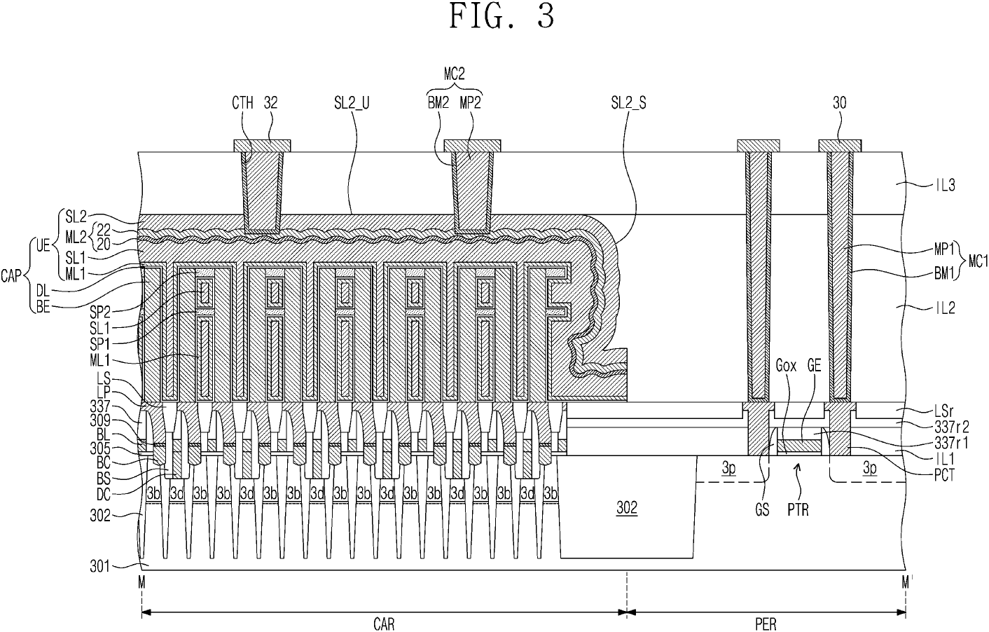

FIG. 1 illustrates a plan view showing a semiconductor memory device according to some embodiments of the present inventive concepts. FIG. 2 illustrates a cross-sectional view taken along lines K-K′ and J-J′ of FIG. 1. FIG. 3 illustrates a cross-sectional view taken along line M-M′ of FIG. 1.

Referring to FIGS. 1 to 3, a semiconductor memory device according to the present embodiment may be a dynamic random access memory (DRAM) device. A semiconductor substrate 301 may be provided which includes a cell array region CAR and a peripheral region PER. The peripheral region PER may be disposed around the cell array region CAR. The peripheral region PER may include peripheral circuits for driving word lines WL and bit lines BL disposed on the cell array region CAR. The peripheral region PER may be called a core region or a peripheral circuit region.

The semiconductor substrate 301 may be provided therein with a device isolation layer 302 that defines cell active sections ACTC and a peripheral active section ACTP. The device isolation layer 302 may be disposed in a trench TCH. Each of the cell active sections ACTC may have an isolated shape. Each of the cell active sections ACTC may have a bar shape elongated in a first direction X1 when viewed in plan view. The semiconductor substrate 301 may be, for example, a monocrystalline silicon substrate or a silicon-on-insulator (SOI) substrate. The device isolation layer 302 may include an oxide liner, a nitride liner, and a buried dielectric layer. The cell active sections ACTC may be arranged and/or extend in parallel to each other in the first direction X1 such that one of the cell active sections ACTC may have an end adjacent to a center of a neighboring one of the cell active sections ACTC.

The word lines WL may run across the cell active sections ACTC. The word lines WL may be disposed in grooves GR1 formed in the device isolation layer 302 and the cell active sections ACTC. The word lines WL may be parallel to a second direction X2 that intersects the first direction X1. For example, the word lines WL may extend in the second direction X2. The word lines WL may be buried in the semiconductor substrate 301.

The word lines WL may be formed of a conductive material. A gate dielectric layer 307 may be disposed between each of the word lines WL and an inner surface of each groove GR1. Although not shown, the grooves GR1 may have their bottom surfaces located relatively deep in the device isolation layer 302 and relatively shallow in the cell active sections ACTC. For example, the bottom surfaces of the grooves GR1 may be deeper/lower in the device isolation layer 302 than in the cell active sections ACTC. The gate dielectric layer 307 may include at least one selected from thermal oxide, silicon nitride, silicon oxynitride, and high-k dielectric. The word lines WL may have their curved bottom surfaces. For example, the word lines WL may have round bottom surfaces in a cross-sectional view.

A first impurity region 3d may be disposed in the cell active section ACTC between a pair of word lines WL, and a pair of second impurity regions 3b may be disposed in opposite edge portions of the cell active section ACTC. The first and second impurity regions 3d and 3b may be doped with, for example, n-type impurities. The first impurity region 3d may correspond to or may be a common drain region, and the second impurity regions 3b may correspond to or may be source regions.

A transistor may be constituted by each of the word lines WL and its adjacent first and second impurity regions 3d and 3b. As the word lines WL are disposed in the grooves GR1, each of the word lines WL may have thereunder a channel region whose length becomes increased within a limited planar area. Accordingly, a short-channel effect may be minimized.

The word lines WL may have their top surfaces lower than those of the cell active sections ACTC. A word-line capping pattern 310 may be disposed on each of the word lines WL. The word-line capping patterns 310 may have their linear shapes that extend along longitudinal directions of the word lines WL, and may cover entire top surfaces of the word lines WL. The grooves GR1 may have inner spaces that are not occupied by the word lines WL, and the word-line capping patterns 310 may fill the unoccupied inner spaces of the grooves. The word-line capping patterns 310 may be formed of, for example, a silicon nitride layer.

An interlayer dielectric pattern 305 may be disposed on the semiconductor substrate 301. The interlayer dielectric pattern 305 may be formed of a single layer or multiple layers including at least one selected from a silicon oxide layer, a silicon nitride layer, and a silicon oxynitride layer. Multiple interlayer dielectric patterns 305 may be formed to have island shapes spaced apart from each other when viewed in plan. The interlayer dielectric pattern 305 may be formed to simultaneously cover end portions of two adjacent cell active sections ACTC. For example one interlayer dielectric pattern 305 may vertically overlap two adjacent cell active sections ACTC.

The semiconductor substrate 301, the device isolation layer 302, and an upper portion of the word-line capping pattern 310 may be partially recessed to form a first recess region R1. The first recess region R1 may have a sidewall aligned with that of the interlayer dielectric pattern 305. For example, a portion of the sidewall of the first recess region R1 and a side surface of the interlayer dielectric pattern 305 may be formed on the same plane extending in a vertical direction.

The bit lines BL may be disposed on the interlayer dielectric pattern 305. The bit lines BL may cross over the word-line capping patterns 310 and the word lines WL. The bit lines BL may be parallel to a third direction X3 that intersect the first and second directions X1 and X2. Each of the bit lines BL may include or be formed of a bit-line polysilicon pattern 330, a bit-line diffusion stop pattern 331, and a bit-line metal-containing pattern 332 that are sequentially stacked. The bit-line polysilicon pattern 330 may include or be formed of impurity-doped polysilicon. The bit-line diffusion stop pattern 331 may include or be formed of metal nitride, such as titanium nitride. The bit-line metal-containing pattern 332 may include at least one selected from metal (e.g., tungsten, titanium, or tantalum) and conductive metal nitride (e.g., titanium nitride, tantalum nitride, or tungsten nitride). A bit-line capping pattern 337 may be disposed on each of the bit lines BL. The bit-line capping patterns 337 may be formed of a dielectric material, such as a silicon nitride layer.

Bit-line contacts DC may be disposed in the first recess regions R1 that intersect the bit lines BL. The bit-line contacts DC may include or be formed of impurity-doped polysilicon or impurity-undoped polysilicon. The bit-line contact DC may have a sidewall in contact with that of the interlayer dielectric pattern 305. When viewed in a plan view as shown in FIG. 1, the bit-line contact DC may have a concave lateral surface in contact with the interlayer dielectric pattern 305. The bit-line contact DC may electrically connect the first impurity region 3d to the bit line BL.

The first recess region R1 may have an empty space (an area) that is not occupied by the bit-line contact DC, and a lower buried dielectric pattern 341 may occupy the empty space (the area not occupied by the bit-line contact DC) of the first recess region R1. The lower buried dielectric pattern 341 may be formed of a single layer or multiple layers including at least one selected from a silicon oxide layer, a silicon nitride layer, and a silicon oxynitride layer.

Storage node contacts BC may be disposed between a pair of neighboring bit lines BL. The storage node contacts BC may be spaced apart from each other. The storage node contacts BC may include or be formed of impurity-doped polysilicon. The storage node contacts BC may have their concave top surfaces. The bit lines BL may be provided therebetween with a dielectric pattern (not shown) disposed between the storage node contacts BC.

A bit-line spacer BS may be disposed between the storage node contact BC and the bit line BL. The bit-line spacer BS may include a first sub-spacer 321 and a second sub-spacer 325 that are spaced apart from each other across a gap region GP. The gap region GP may be called an air gap. The first sub-spacer 321 may cover a sidewall of the bit line BL and a sidewall of the bit-line capping pattern 337. The second sub-spacer 325 may be adjacent to the storage node contact BC. The first sub-spacer 321 and the second sub-spacer 325 may include or be formed of the same material. For example, the first sub-spacer 321 and the second sub-spacer 325 may include or be formed of a silicon nitride layer.

The second sub-spacer 325 may have a top end whose height is lower than that of a top end of the first sub-spacer 321. The first sub-spacer 321 may extend to cover/contact a sidewall of the bit-line contact DC and also to cover/contact a sidewall and a bottom surface of the first recess region R1. For example, the first sub-spacer 321 may be interposed between the bit-line contact DC and the lower buried dielectric pattern 341, between the semiconductor substrate 301 and the lower buried dielectric pattern 341, and between the device isolation layer 302 and the lower buried dielectric pattern 341.

A storage node ohmic layer 309 may be disposed on the storage node contact BC. The storage node ohmic layer 309 may include or be formed of metal silicide. For example, the storage node ohmic layer 309 may include or be formed of cobalt silicide. The storage node ohmic layer 309, the first and second sub-spacers 321 and 325, and the bit-line capping pattern 337 may be conformally covered with a diffusion stop pattern 311a. The diffusion stop pattern 311a may include or be formed of metal nitride, such as a titanium nitride layer or a tantalum nitride layer. A landing pad LP may be disposed on the diffusion stop pattern 311a. The landing pad LP may be formed of a material that contains metal, such as tungsten. The landing pad LP may have an upper portion that covers a top surface of the bit-line capping pattern 337 and may have a width greater than that of the storage node contact BC. A center of the landing pad LP may shift in the second direction X2 away from a center of the storage node contact BC. A portion of the bit line BL may vertically overlap the landing pad LP. An upper sidewall of the bit-line capping pattern 337 may overlap the landing pad LP and may be covered with a third sub-spacer 327. A second recess region R2 may be formed on another upper sidewall of the bit-line capping pattern 337.

A sum of widths of the first sub-spacer 321 and the third sub-spacer 327, e.g., in the second direction X2, on an upper portion of the bit-line spacer BS may be less than a sum of widths of the first sub-spacer 321, the gap region GP, and the second sub-spacer 325, e.g., in the second direction X2, on a lower portion of the bit-line spacer BS. Such a configuration may increase a formation margin for landing pads LP which will be discussed below. As a result, the landing pad LP and the storage node contact BC may be prevented from being disconnected from each other.

A landing-pad separation pattern LS may be disposed in the second recess region R2. The landing-pad separation pattern LS may define a top end of the gap region GP. The landing-pad separation pattern LS may include of be formed of a silicon nitride layer, a silicon oxide layer, a silicon oxynitride layer, a silicon carbonitride layer, or a porous layer. The landing-pad separation pattern LS may have a top surface coplanar with those of the landing pads LP. The landing-pad separation pattern LS may be covered with an etch stop layer EL disposed between bottom electrodes BE which will be discussed below. The etch stop layer EL may include or be formed of a dielectric material, such as a silicon nitride layer, a silicon oxide layer, or a silicon oxynitride layer.

Bottom electrodes BE may be disposed on corresponding landing pads LP. The bottom electrode BE may include at least one selected from an impurity-doped polysilicon layer, a metal nitride layer such as a titanium nitride layer, and a metal layer such as a tungsten layer, an aluminum layer, and a copper layer. The bottom electrode BE may have a circular columnar shape, a hollow cylindrical shape, or a cup shape.

A support pattern SP may be provided on upper sidewalls of the bottom electrodes BE. The support pattern SP may include or be formed of a dielectric material, such as a silicon nitride layer, a silicon oxide layer, a silicon oxynitride layer, or a silicon carbonitride layer (SiCN). The support pattern SP may contact and connect at least portions of sidewalls of the bottom electrodes BE. The support pattern SP may prevent collapse of the bottom electrodes BE during fabrication process for the semiconductor memory device. The support pattern SP may have support holes that expose the sidewalls of the bottom electrodes BE.

The support pattern SP may be provided as a single layer located at one level as shown in FIG. 2. Alternatively, the support pattern SP may be provided as a plurality of layers at a plurality of levels as shown in FIG. 3. For example, the support pattern SP may include a first support pattern SP1 at a first level and a second support pattern SP2 at a second level higher than the first level. The second support pattern SP2 may be in contact with upper sidewalls of the bottom electrodes BE. The first support pattern SP1 may be in contact with intermediate sidewalls of the bottom electrodes BE. The first support pattern SP1 may have a sidewall aligned with that of the second support pattern SP2. For example, a sidewall of the first support pattern SP1 and a sidewall of the second support pattern SP2 may be formed on the same plane extending in a vertical direction. The first and second support patterns SP1 and SP2 may have their edges adjacent to a boundary between the cell array region CAR and the peripheral region PER, which edges may laterally protrude from an outermost bottom electrodes BE. Although not shown, the support pattern SP may include a third support pattern located at a level different from those of the first and second support patterns SP1 and SP2.

A dielectric layer DL may conformally cover surfaces of the bottom electrodes BE and a surface of the support pattern SP (or SP1 and SP2). The dielectric layer DL may include or be formed of a material, such as metal oxide, whose dielectric constant is greater than that of a silicon oxide layer. The dielectric layer DL may have a single-layered or multi-layered structure formed of at least one selected from aluminum oxide, zirconium oxide, hafnium oxide, lanthanum oxide, iridium oxide, and ruthenium oxide. The dielectric layer DL may be covered with a top electrode UE. A capacitor CAP may be constituted by the bottom electrode BE, the dielectric layer DL, and the top electrode UE.

Referring to FIGS. 2 and 3, the top electrode UE may include or be formed of a first metal layer ML1, a silicon-germanium layer SL1, a second metal layer ML2, and a silicon layer SL2 that are sequentially stacked. The silicon-germanium layer SL1 may be called a first semiconductor layer or an impurity-doped first semiconductor layer. The silicon layer SL2 may be called a second semiconductor layer or an impurity-doped second semiconductor layer.

The first metal layer ML1 may be formed of a metallic material whose step coverage is excellent, and may conformally cover the surfaces of the bottom electrodes BE and the surface of the support pattern SP (or SP1 and SP2). The first metal layer ML1 may include or be formed of, for example, titanium nitride. The first metal layer ML1 may have a first thickness T1.

The silicon-germanium layer SL1 may be positioned on and in contact with the first metal layer ML1. A portion of the silicon-germanium layer SL1 may be inserted into and fill a space between the bottom electrodes BE and a space between the first and second support patterns SP1 and SP2. The silicon-germanium layer SL1 may have a second thickness T2 greater than the first thickness T1.

The first metal layer ML1 may provide the semiconductor memory device (or the semiconductor substrate 301) with a first stress. The silicon-germanium layer SL1 may provide the semiconductor memory device (or the semiconductor substrate 301) with a second stress different from the first stress. An action direction of the first stress may be different from that of the second stress. The difference in action direction between the first and second stresses may prevent/reduce warpage of the semiconductor memory device (or the semiconductor substrate 301).

The silicon-germanium layer SL1 may include first dopants. The silicon-germanium layer SL1 may be doped with the first dopants. The first dopants may be n-type impurities (e.g., phosphorus or arsenic) or p-type impurities (e.g., boron). The first dopants may be, for example, boron. As shown in FIG. 3, a crystal grain of silicon-germanium may allow the silicon-germanium layer SL1 to have an uneven structure at top and lateral surfaces thereof. A surface roughness at the top surface of the silicon-germanium layer SL1 may be the same as or similar to that at the lateral surface of the silicon-germanium layer SL1. The surface roughness at the top and lateral surfaces of the silicon-germanium layer SL1 may have a root-mean-square (RMS) of greater than about 10 nm and equal to or less than about 1,000 nm.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

The second metal layer ML2 may have a third thickness T3. The third thickness T3 may be less than the second thickness T2. The second metal layer ML2 may be conformally formed on the silicon-germanium layer SL1. For example, the third thickness T3 of the second metal layer ML2 may be constant irrespective of position. A surface of the second metal layer ML2 may not be flat, but may have an uneven structure caused by an effect of profile at the surface of the silicon-germanium layer SL1. The second metal layer ML2 may have the same or similar surface roughness at top and lateral surfaces thereof. The second metal layer ML2 may have a root-mean-square (RMS) surface roughness of greater than about 10 nm and equal to or less than about 1,000 nm at top and lateral surface thereof.

The second metal layer ML2 may have a single-layered or multi-layered structure formed of one or more metals. For example, the second metal layer ML2 may have a single-layered or multi-layered structure formed of at least one selected from titanium, titanium nitride, tungsten, tantalum, tantalum nitride, aluminum, ruthenium, molybdenum, and iridium. In the present embodiment, the second metal layer ML2 may include or be formed of a first sub-metal layer 20 and a second sub-metal layer 22 that are sequentially stacked. The second sub-metal layer 22 may include or be formed of, for example, tungsten. The first sub-metal layer 20 may increase an adhesive force between the second sub-metal layer 22 and the silicon-germanium layer SL1. Therefore, the first sub-metal layer 20 may reduce or prevent delamination of the second sub-metal layer 22. The first sub-metal layer 20 may include or be formed of, for example, titanium. In this description, the first sub-metal layer 20 may be called a conductive adhesive layer. In this description, the second sub-metal layer 22 may be called a second metal layer.

The silicon layer SL2 may be formed of an amorphous silicon layer into which the first dopants are doped or not (or in which the first dopants are included or not). An amount of the first dopants (e.g., boron) included in the silicon-germanium layer SL1 may be greater than an amount of the first dopants (e.g., boron) included in the silicon layer SL2. For example, the amount of the first dopants (e.g., boron) included in the silicon layer SL2 may be less than the amount of the first dopants (e.g., boron) included in the silicon-germanium layer SL1. In this description, an amount of dopants may be called a concentration or an atomic concentration. For example, an amount of boron doped in the silicon-germanium layer SL1 may range from 0.1 at% to about 15 at%. The amount of the first dopants (e.g., boron) included in the first silicon layer SL2 may be about 0% to about 90% of the amount of the first dopants (e.g., boron) included in the silicon-germanium layer SL1.

The silicon layer SL2 may have a fourth thickness T4 greater than the third thickness T3. A top surface SL2_U of the silicon layer SL2 may be flatter/smoother than a lateral surface SL2_S of the silicon layer SL2. The top surface SL2_U of the silicon layer SL2 may have a surface roughness less than that of the lateral surface SL2_S of the silicon layer SL2. The top surface SL2_U of the silicon layer SL2 may have a surface roughness equal to or less than about 10 nm RMS.

The second metal layer ML2 may provide the semiconductor memory device (or the semiconductor substrate 301) with a third stress. The silicon layer SL2 may provide the semiconductor memory device (or the semiconductor substrate 301) with a fourth stress different from the third stress. An action direction of the third stress may be different from that of the fourth stress. The difference in action direction between the third and fourth stresses may prevent/reduce warpage of the semiconductor memory device (or the semiconductor substrate 301).

In the semiconductor substrate 301, trenches TCH may be formed to lie in the device isolation layer 302, and grooves GR1 may be formed to have grooves GR1 in which the word lines WL are disposed. There may be present dangling bonds in inner sidewalls of the trenches TCH and the grooves GR1. The dangling bonds may cause a leakage current when the semiconductor memory device is performed, and may thus reduce refresh characteristics.

The silicon layer SL2 may include hydrogen atoms. The hydrogen atoms may diffuse from the silicon layer SL2 toward the semiconductor substrate 301, and may thus combine with the dangling bonds at the inner sidewalls of the trenches TCH and the grooves GR1. Accordingly, the present embodiment may be beneficial to improve refresh characteristics during operation of the semiconductor memory device.

A peripheral transistor PTR may be disposed on the peripheral region PER. The peripheral transistor PTR may include a peripheral gate dielectric layer Gox, a peripheral gate electrode GE, a peripheral capping pattern 337rl, and a peripheral spacer GS that cover sidewalls of the peripheral gate dielectric layer Gox, the peripheral gate electrode GE, and the peripheral capping pattern 337r1. The peripheral transistor PTR may further include a peripheral source/drain region 3p disposed in the semiconductor substrate 301 on opposite sides of the peripheral gate dielectric layer Gox, e.g., in a cross-section view. The peripheral region PER may be covered with a first interlayer dielectric layer IL 1. The first interlayer dielectric layer IL1 may include or be formed of, for example, silicon oxide. The first interlayer dielectric layer IL1 may have a top surface coplanar with that of the peripheral capping pattern 337r1. A first dielectric layer 337r2 may be disposed on the first interlayer dielectric layer IL1. The first dielectric layer 337r2 and the peripheral capping pattern 337r1 may include or be formed of the same material as that of the bit-line capping pattern 337. The first dielectric layer 337r2 and the peripheral capping pattern 337r1 may include or be formed of, for example, silicon nitride. A sum of a maximum thickness of the first dielectric layer 337r2 and a thickness of the peripheral capping pattern 337r1 may be the same as a thickness of the bit-line capping pattern 337.

A first peripheral contact plug PCT may penetrate the first dielectric layer 337r2 and the first interlayer dielectric layer IL1 to contact the peripheral source/drain region 3p. A portion of the first peripheral contact plug PCT may protrude onto the first dielectric layer 337r2. A second dielectric layer LSr may be disposed on the first dielectric layer 337r2. The second dielectric layer LSr may include or be formed of the same material as that of the landing-pad separation pattern LS. A portion of the second dielectric layer LSr may extend into the first dielectric layer 337r2, e.g., in a vertical direction. For example, the second dielectric layer LSr may have a bottom surface lower than a top end of the first dielectric layer 337r2. The landing pad LP, the landing-pad separation pattern LS, the second dielectric layer LSr, and the first peripheral contact plug PCT may have their top surfaces that are coplanar with each other.

On the peripheral region PER, a second interlayer dielectric layer IL2 may be disposed on the second dielectric layer LSr. The second interlayer dielectric layer IL2 may have a single-layered or multi-layered structure formed of at least one selected from silicon oxide, silicon nitride, silicon oxynitride, and porous dielectric (e.g., SiOCH). The second interlayer dielectric layer IL2 may be in contact with a lateral surface of the top electrode UE. The dielectric layer DL, the first metal layer ML1, the silicon-germanium layer SL1, the second metal layer ML2, and the silicon layer SL2 may have their lower sidewalls that are vertically aligned with each other adjacent to a boundary between the cell array region CAR and the peripheral region PER. For example, sidewalls of the dielectric layer DL, the first metal layer ML1, the silicon-germanium layer SL1, the second metal layer ML2, and the silicon layer SL2 may be formed on the same plane extending in a vertical direction at or near the boundary between the cell array region CAR and the peripheral region PER. The second interlayer dielectric layer IL2 may be in contact with the lower sidewalls of the dielectric layer DL, the first metal layer ML1, the silicon-germanium layer SL1, the second metal layer ML2, and the silicon layer SL2, e.g., at or near the boundary between the cell array region CAR and the peripheral region PER. The second interlayer dielectric layer IL2 may have a top surface coplanar with a top surface SL2_U of the top electrode UE.

A third interlayer dielectric layer IL3 may be disposed on the top electrode UE and the second interlayer dielectric layer IL2. The third interlayer dielectric layer IL3 may have a single-layered or multi-layered structure formed of at least one selected from silicon oxide, silicon nitride, silicon oxynitride, and porous dielectric (e.g., SiOCH).

On the peripheral region PER, second peripheral contact plugs MC1 may penetrate the third interlayer dielectric layer IL3 and the second interlayer dielectric layer IL2 to contact corresponding first peripheral contact plugs PCT. The second peripheral contact plugs MC1 may each include a first contact diffusion stop pattern BM1 and a first contact metal pattern MP1.

On the cell array region CAR, the cell contact plugs MC2 may penetrate the third interlayer dielectric layer IL3 to contact the top electrode UE. The cell contact plugs MC2 may each include a second contact diffusion stop pattern BM2 and a second contact metal pattern MP2. The first and second contact diffusion stop patterns BM1 and BM2 may each include or be formed of a metal nitride, such as titanium nitride, tantalum nitride, and tungsten nitride. The first and second contact metal patterns MP1 and MP2 may each include or be formed of a metal, such as tungsten, aluminum, and copper. In the present embodiment, the cell contact plugs MC2 may penetrate the silicon layer SL2 to contact the second metal layer ML2. In this case, the silicon layer SL2 may exclude boron. For example, the silicon layer SL2 may not include boron, e.g., boron atoms.

The second peripheral contact plugs MC1 may be provided thereon with peripheral lines 30. For example, the peripheral lines 30 may contact the second peripheral contact plugs MC1. The cell contact plugs MC2 may be provided thereon with cell lines 32. For example, the cell lines 32 may contact the cell contact plugs MC2.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

Boron may be doped to provide conductivity to a semiconductor layer included in the top electrode UE. Boron has two naturally occurring isotopes ¹¹B whose atomic weight is 11 and ¹⁰B whose atomic weight is 10. The isotope ¹⁰B occupies about 20% of natural boron. When an aircraft is used to export ¹⁰B-containing semiconductor memory devices to foreign countries, cosmic rays may decompose ¹⁰B atoms included in the semiconductor memory device and thus the semiconductor memory device may be damaged. This phenomenon may be called air defects.

In the semiconductor memory device according to the present embodiment, the top electrode UE may include the first metal layer ML1 and the second metal layer ML2, and thus the top electrode UE may have therein a reduced relative proportion of the semiconductor layer (e.g., silicon-germanium layer and/or a silicon layer). Therefore, the top electrode UE may have a reduced absolute amount of boron therein. In addition, an amount of boron in the silicon layer SL2 may be less than an amount of boron in the silicon-germanium layer SL1, and thus the top electrode UE may have a reduced absolute amount of boron therein, e.g., comparing with a device having a structure of a top electrode UE which does not have the first metal layer ML1, the second metal layer ML2 and/or the silicon layer SL2. Accordingly, it may be possible/beneficial to decrease air defects of the semiconductor memory device according to the present inventive concepts.

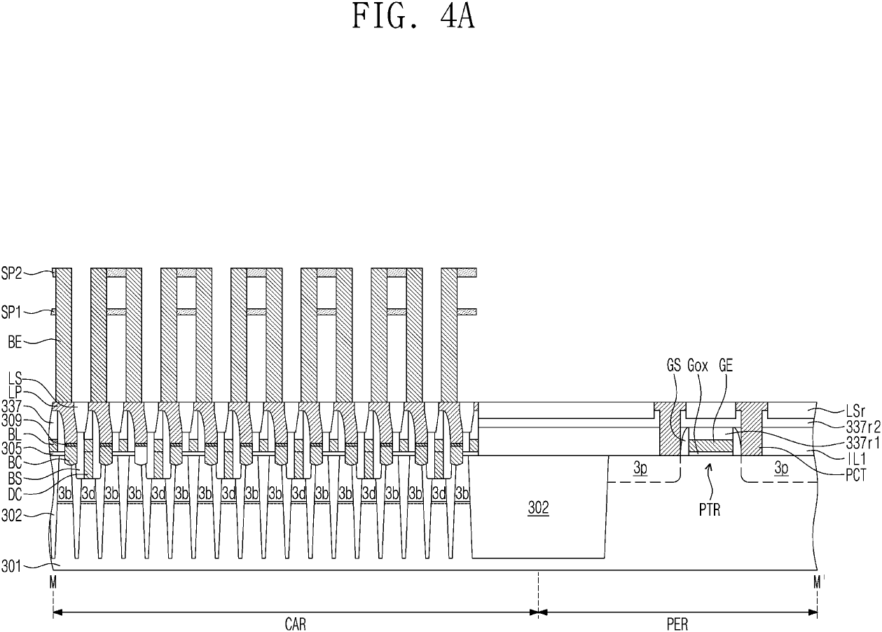

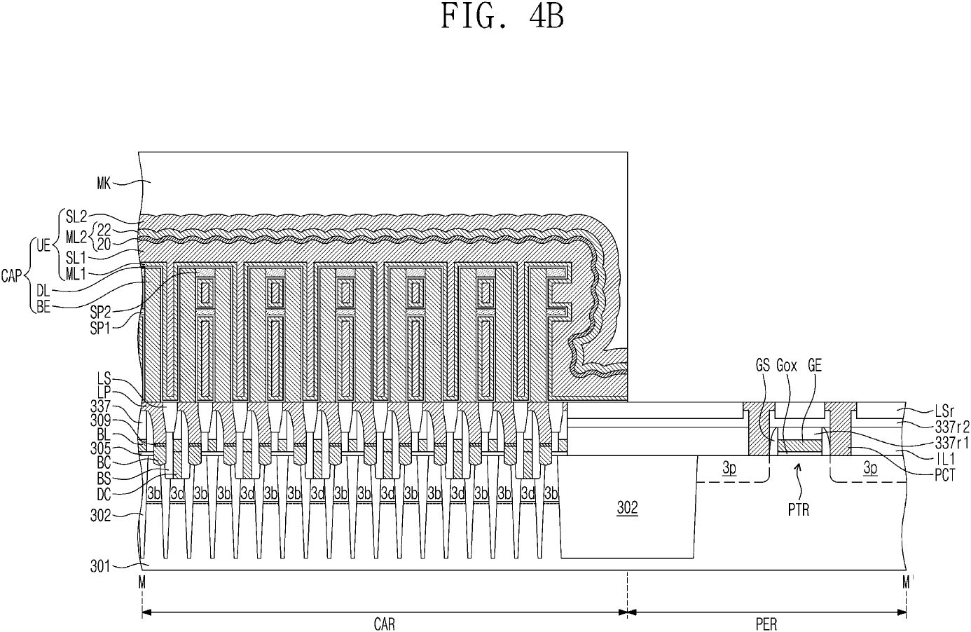

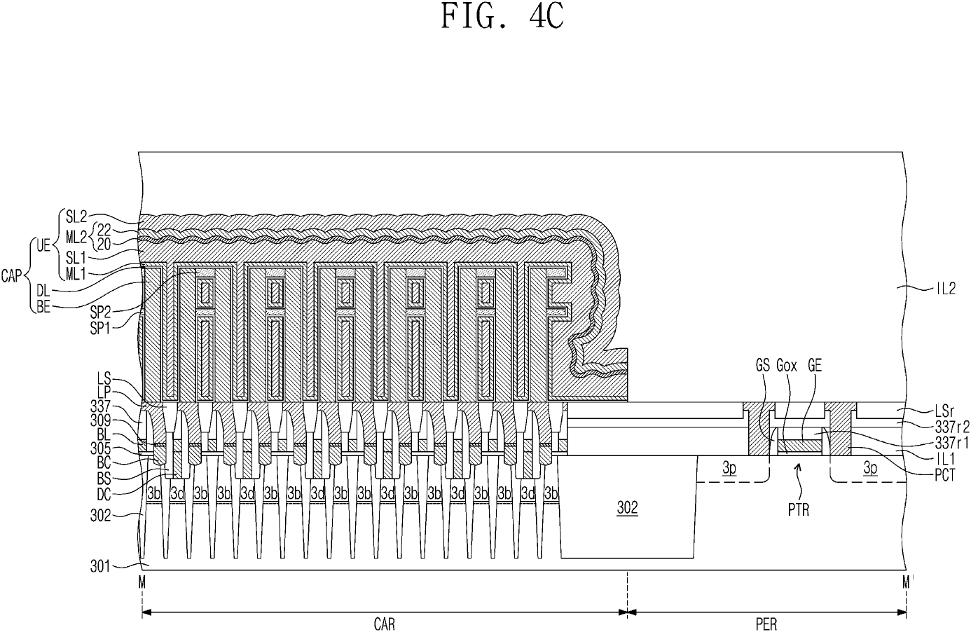

FIGS. 4A to 4C illustrate cross-sectional views showing a method of fabricating the semiconductor memory device of FIG. 3.

Referring to FIG. 4A, a semiconductor substrate 301 may be provided which has a cell array region CAR and a peripheral region PER. Typical processes may be performed to form word lines WL, bit lines BL, a peripheral transistor PTR, bottom electrodes BE, and support patterns SP1 and SP2 of FIGS. 2 and 3 on the semiconductor substrate 301.

Referring to FIG. 4B, a dielectric layer DL, a first metal layer ML1, a silicon-germanium layer SL1, a second metal layer ML2, and a silicon layer SL2 may be sequentially stacked on an entire surface of the semiconductor substrate 301. The dielectric layer DL, the first metal layer ML1, the silicon-germanium layer SL1, the second metal layer ML2, and the silicon layer SL2 may each be formed by performing atomic layer deposition (ALD), chemical vapor deposition (CVD), or physical vapor deposition (PVD). While the silicon-germanium layer SL1 is formed, the silicon-germanium layer SL1 may be in-situ doped with first dopants (e.g., boron). The silicon layer SL2 may be formed of an amorphous silicon layer. When the silicon layer SL2 contains the first dopants, the first dopants (e.g., boron) may be in-situ doped while the silicon layer SL2 is formed.

Grains of silicon-germanium may allow the silicon-germanium layer SL1 to have an uneven surface. A surface profile of the silicon-germanium layer SL1 may be transferred to allow the second metal layer ML2 and the silicon layer SL2 to also have their uneven surfaces.

On or around a boundary between the cell array region CAR and the peripheral region PER, the first and second support patterns SP1 and SP2 may outwardly/laterally protrude from a sidewall of an outermost bottom electrode BE. Therefore, a top electrode UE, which will be discussed below, may have an upper sidewall that laterally protrudes toward the peripheral region PER.

After forming the silicon-germanium layer SL1 and before stacking the second metal layer ML2, an annealing process may be additionally performed to crystallize the silicon-germanium layer SL1. In this case, the annealing process may be executed at about 550° C. or lower, and thus no damage may be caused to the dielectric layer DL. The silicon layer SL2 may not undergo an annealing process for crystallization.

Subsequently, a mask pattern MK may be formed on the silicon layer SL2. The mask pattern MK may be formed to cover top and lateral surfaces of the silicon layer SL2. The mask pattern MK may be, for example, a photoresist pattern or a spin-on-hardmask (SOH) pattern. The mask pattern MK may cover the cell array region CAR and expose the peripheral region PER. The mask pattern MK may be used as an etching mask to remove the dielectric layer DL, the first metal layer ML1, the silicon-germanium layer SL1, the second metal layer ML2, and the silicon layer SL2 from the peripheral region PER, such that a top electrode UE may be formed and the second dielectric layer LSr may be exposed.

Referring to FIG. 4C, the mask pattern MK may be removed. The mask pattern MK may be removed by employing an ashing process that uses oxygen. In this step, the silicon layer SL2 may serve as a protection mask for prevention of oxidation of the second metal layer ML2. When the silicon layer SL2 is absent, oxygen may oxidize the second metal layer ML2 into metal oxide to remarkably increase an electrical resistance, and the top electrode UE may thus be difficult to act as an electrode.

Referring to FIG. 4C, the mask pattern MK may be removed to expose top and lateral surfaces of the top electrode UE. A second interlayer dielectric layer IL2 may be formed on the entire surface of the semiconductor substrate 301, covering the top electrode UE. Referring to FIG. 3, the second interlayer dielectric layer IL2 may undergo a polishing process such as chemical mechanical polishing (CMP). The polishing process may expose a top surface SL2_U of the silicon layer SL2 included in the top electrode UE. In this step, the silicon layer SL2 may serve as a CMP stop layer. As the silicon layer SL2 serves as a CMP stop layer, the second metal layer ML2 may not be exposed. Therefore, a CMP apparatus may not be contaminated with metal included in the second metal layer ML2.

The polishing process may planarize the top surface SL2_U of the silicon layer SL2. For example, the silicon layer SL2 may be relatively flat at its top surface SL2_U and uneven at its lateral surface SL2_S. For example, the top surface SL2_U of the silicon layer SL2 may be smoother than the lateral surface SL2_S of the silicon layer SL2. The second interlayer dielectric layer IL2 may cover the peripheral region PER. A third interlayer dielectric layer IL3 may be stacked on the second interlayer dielectric layer IL2 and the top electrode UE. Typical processes may be performed to form second peripheral contact plugs MC1, cell contact plugs MC2, peripheral lines 30, and cell lines 32. To form the cell contact plugs MC2, the third interlayer dielectric layer IL3 and the silicon layer SL2 may be etched to form cell contact holes CTH. In this step, because the silicon layer SL2 has the flat top surface SL2_U, the cell contact holes CTH may be formed to have their uniform depth. Accordingly, the present embodiment may be beneficial to fabricate a semiconductor memory device capable of preventing process defects and increasing reliability.

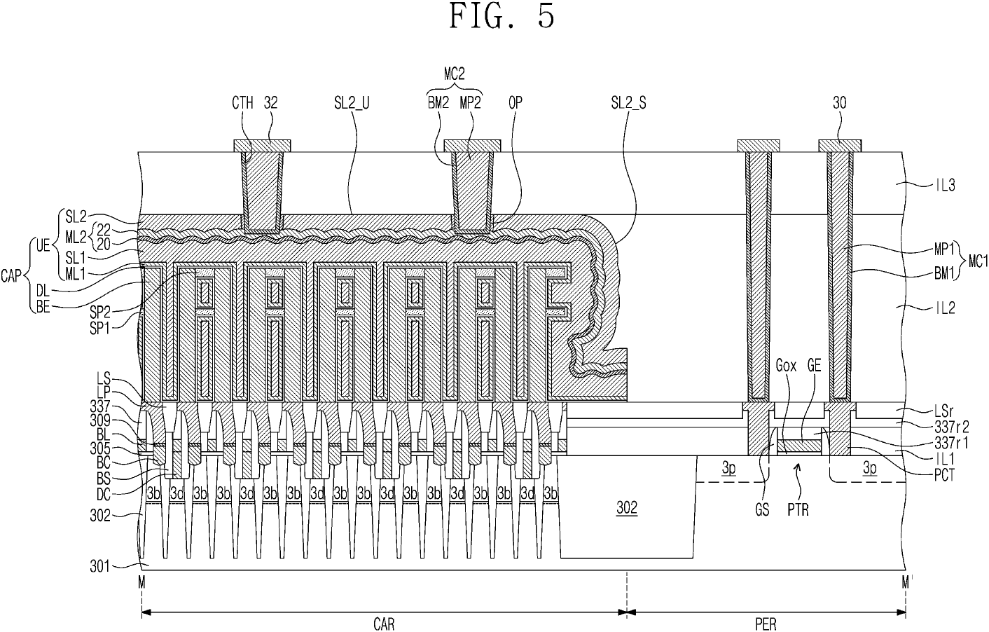

FIG. 5 illustrates a cross-sectional view taken along line M-M′ of FIG. 1.

Referring to FIG. 5, a semiconductor memory device according to the present embodiment may be configured such that an ohmic pattern OP may be interposed between the cell contact plug MC2 and the silicon layer SL2. The ohmic pattern OP may be formed of metal silicide, such as titanium silicide. The second contact diffusion stop pattern BM2 of the cell contact plug MC2 may be formed of a double layer including a titanium layer and a titanium nitride layer.

The following will describe a method of fabricating the semiconductor memory device of FIG. 5. As discussed above, the cell contact hole CTH may be formed to penetrate the third interlayer dielectric layer IL3 and the silicon layer SL2 and to expose a top surface of the second metal layer ML2, and then a titanium layer and a titanium nitride layer for the second contact diffusion stop pattern BM2 may be sequentially and conformally formed in the cell contact holes CTH and on the third interlayer dielectric layer IL3. When the titanium layer is deposited, the titanium layer and the silicon layer SL2 may react to form the ohmic pattern OP. The ohmic pattern OP may be in contact with a lower sidewall of the cell contact plug MC2. Other processes may be identical or similar to those discussed above with respect to other embodiments.

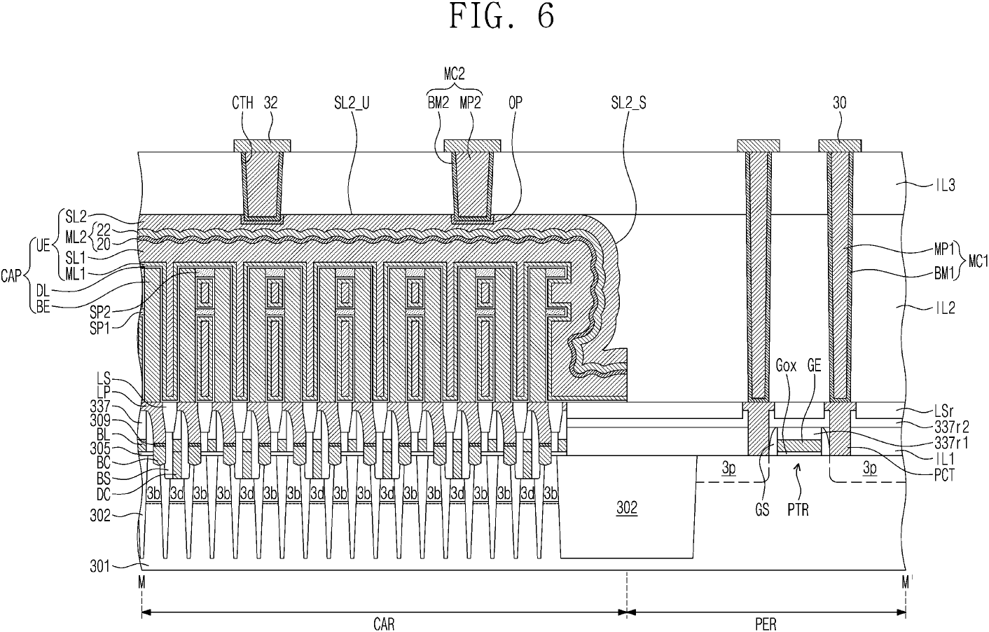

FIG. 6 illustrates a cross-sectional view taken along line M-M′ of FIG. 1.

Referring to FIG. 6, a semiconductor memory device according to the present embodiment may be configured such that the cell contact plug MC2 may not be in contact with the second metal layer ML2 and may be upwardly spaced apart from a top surface of the second metal layer ML2. The cell contact plug MC2 may have a bottom surface positioned in the silicon layer SL2. An ohmic pattern OP may be interposed between the cell contact plug MC2 and the silicon layer SL2. The ohmic pattern OP may be in contact with a lower sidewall of the cell contact plug MC2. Alternatively, the ohmic pattern OP may be in contact with a bottom surface of the cell contact plug MC2. In certain embodiments, the ohmic pattern OP may be in contact with a bottom surface and a lower portion of the sidewall of the cell contact plug MC2 as shown in FIG. 6. Dissimilarly, the ohmic pattern OP may not be in contact with the second metal layer ML2. In the present embodiment, the silicon layer SL2 may be doped with boron. An amount of boron doped in the silicon layer SL2 may be less than an amount of boron doped in the silicon-germanium layer SL1. For example, the amount of boron doped in the silicon layer SL2 may be about 0.01% to about 90% of the amount of boron doped in the silicon-germanium layer SL1. The ohmic pattern OP may be formed of metal silicide, such as titanium silicide. The second contact diffusion stop pattern BM2 of the cell contact plug MC2 may be formed of a double layer including a titanium layer and a titanium nitride layer. Other configurations may be identical or similar to those discussed above.

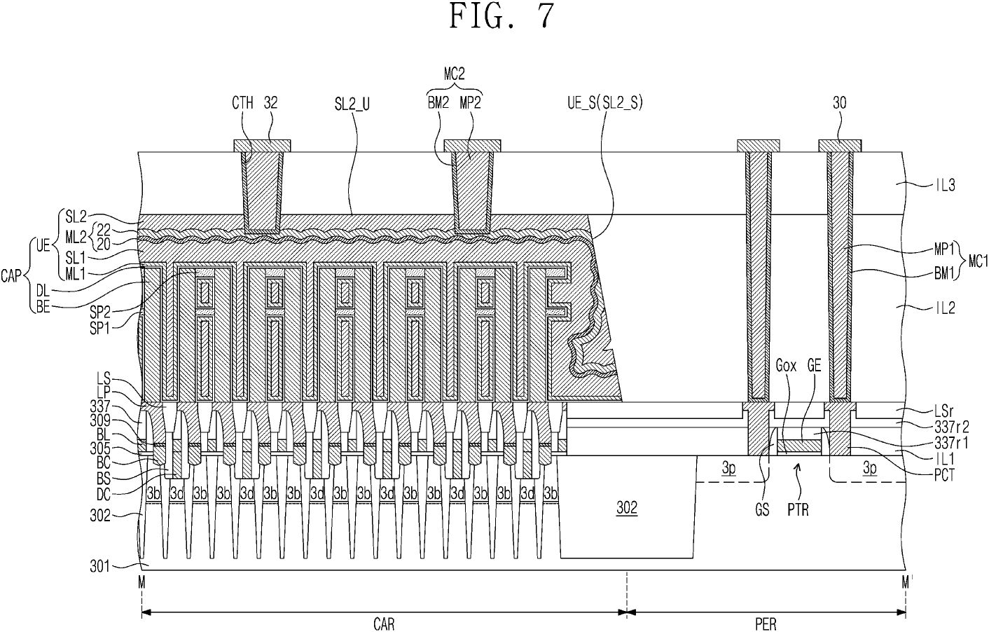

FIG. 7 illustrates a cross-sectional view taken along line M-M′ of FIG. 1.

Referring to FIG. 7, a semiconductor memory device according to the present embodiment may be configured such that the top electrode UE may have an inclined sidewall UE_S, e.g., at a boundary between the cell array region CAR and the peripheral region PER. The second metal layer ML2 may be exposed on an upper portion of the sidewall UE_S of the top electrode UE. The first and second sub-metal layers 20 and 22 of the second metal layer ML2 may be simultaneously exposed on the upper portions of the sidewall UE_S of the top electrode UE. For example, both of the first and second sub-metal layers 20 and 22 of the second metal layer ML2 may be exposed on the upper portions of the sidewall UE_S of the top electrode UE. The silicon-germanium layer SL1 of the top electrode UE may have an upper sidewall that is not covered with the silicon layer SL2. For example, a portion of the silicon-germanium layer SL1 of the top electrode UE may not horizontally overlap the silicon layer SL2. Other configurations may be identical or similar to those discussed with reference to one or more of FIGS. 3, 5, and 6.

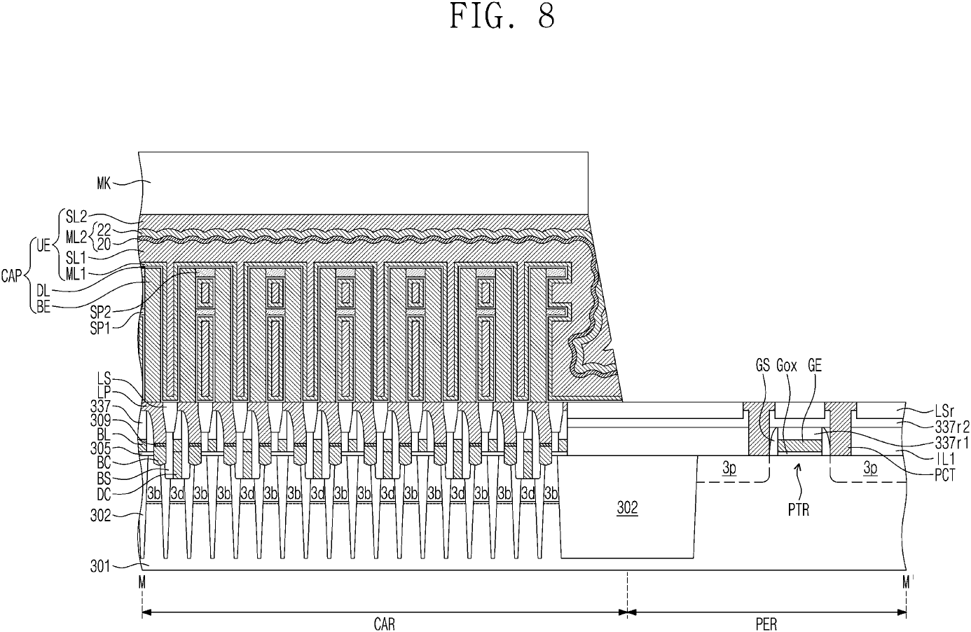

FIG. 8 illustrates a cross-sectional view showing a method of fabricating the semiconductor memory device of FIG. 7.

Referring to FIG. 8, when the mask pattern MK is formed in the step of FIG. 4B, on the cell array region CAR, the mask pattern MK may be formed to cover a top surface of the silicon layer SL2 and to expose a lateral surface of the silicon layer SL2. The mask pattern MK may be used as an etching mask such that the silicon layer SL2, the second metal layer ML2, the silicon-germanium layer SL1, the first metal layer ML1, and the dielectric layer DL may be sequentially etched to form the top electrode UE and to expose the second dielectric layer LSr on the peripheral region PER. In the etching process, an increase in depth of etch-target layers may induce difficulty of access of etchant, and therefore the top electrode UE may be formed to have an inclined sidewall. Subsequent processes may be the same as the ones as discussed above with respect to other embodiments. It may thus be possible to fabricate the semiconductor memory device of FIG. 7.

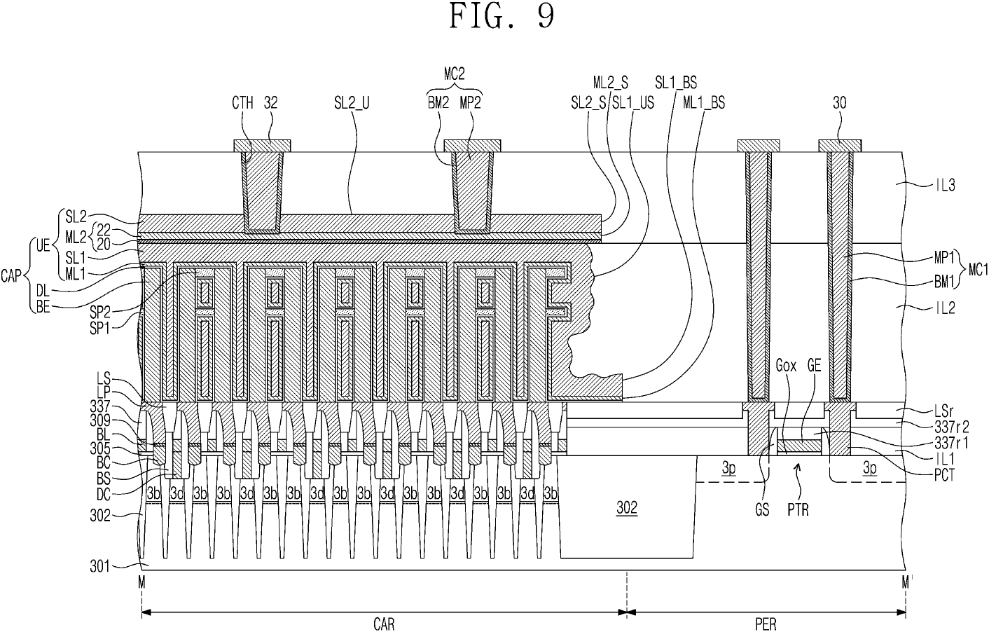

FIG. 9 illustrates a cross-sectional view taken along line M-M′ of FIG. 1.

Referring to FIG. 9, a semiconductor memory device according to the present embodiment may be configured such that the second metal layer ML2 and the silicon layer SL2 may not cover but expose sidewalls of the silicon-germanium layer SL1. A sidewall ML2_S of the second metal layer ML2 may be vertically aligned with a sidewall SL2_S of the silicon layer SL2. For example, the sidewall of the second metal layer ML2 and the sidewall SL2_S of the silicon layer SL2 may be/extend on the same plane extending in the third direction X3 and the vertical direction. The sidewall ML2_S of the second metal layers ML2 and the sidewall SL2_S of the silicon layer SL2 may protrude more laterally, e.g., in the second direction X2, than an upper sidewall SL1_US of the silicon-germanium layer SL1. A lower sidewall ML1_BS of the first metal layer ML1 may be vertically aligned with a lower sidewall SL1_BS of the silicon-germanium layer SL1. For example, the lower sidewall ML1_BS of the first metal layer ML1 and the lower sidewall SL1_BS of the silicon-germanium layer SL1 may be/extend on the same plane extending in the third direction X3 and the vertical direction. The sidewall ML2_S of the second metal layers ML2 and the sidewall SL2_S of the silicon layer SL2 may not be vertically overlap or aligned with the lower sidewall ML1_BS of the first metal layer ML1 and the lower sidewall SL1_BS of the silicon-germanium layer SL1. The lower sidewall ML1_BS of the first metal layer ML1 and the lower sidewall SL1_BS of the silicon-germanium layer SL1 may protrude more laterally, e.g., in the second direction X2, than the sidewall ML2_U of the second metal layers ML2 and the sidewall SL2_U of the silicon layer SL2. The silicon-germanium layer SL1 may be flat at a top surface thereof and uneven at a sidewall thereof. For example, the top surface of the silicon-germanium layer SL1 may be smoother than the sidewall of the silicon-germanium layer SL1. The second metal layer ML2 and the silicon layer SL2 may have their top surfaces that are relatively flat. For example, top surfaces of the second metal layer ML2 and the silicon layer SL2 may be smoother than the sidewall of the silicon-germanium layer SL1. Other configurations may be identical or similar to those discussed in other embodiments above.

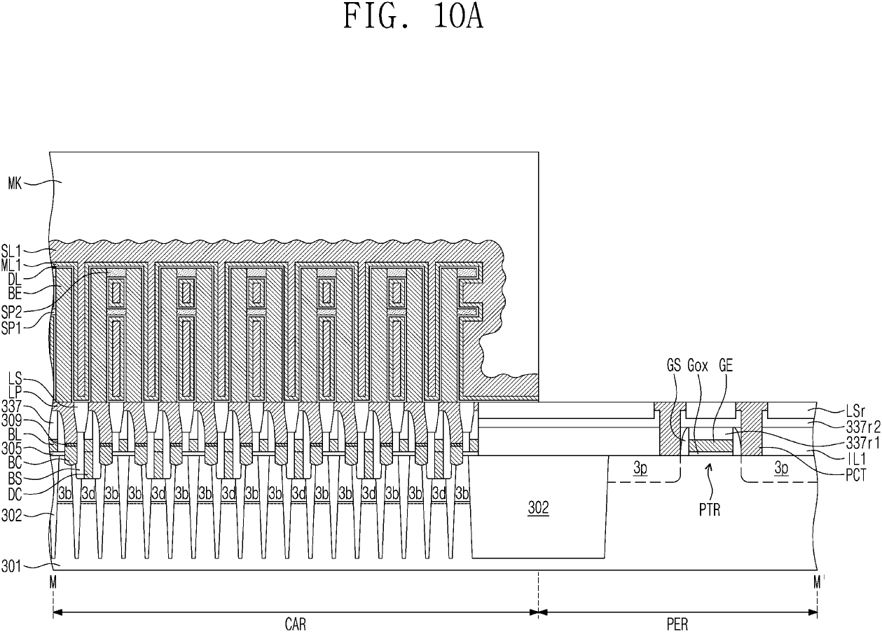

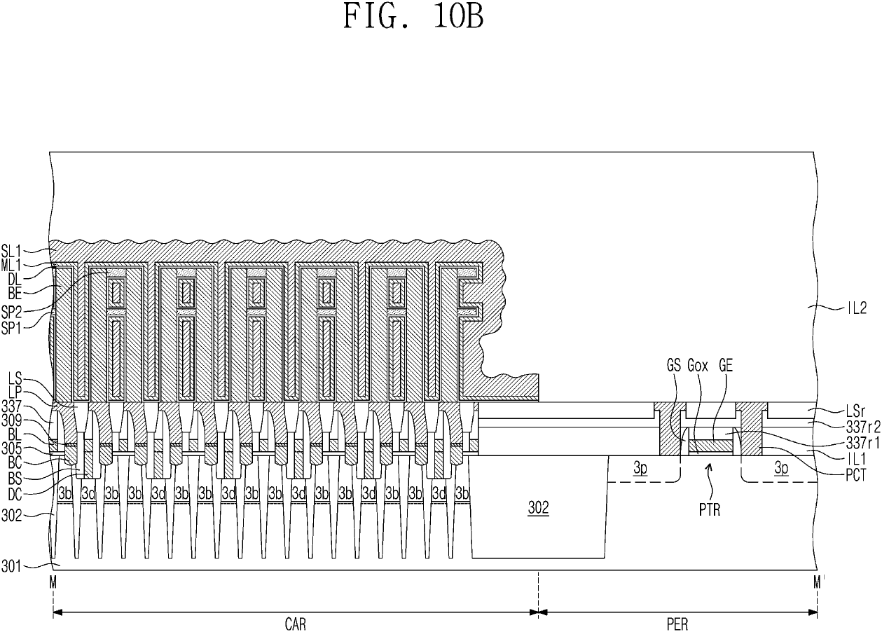

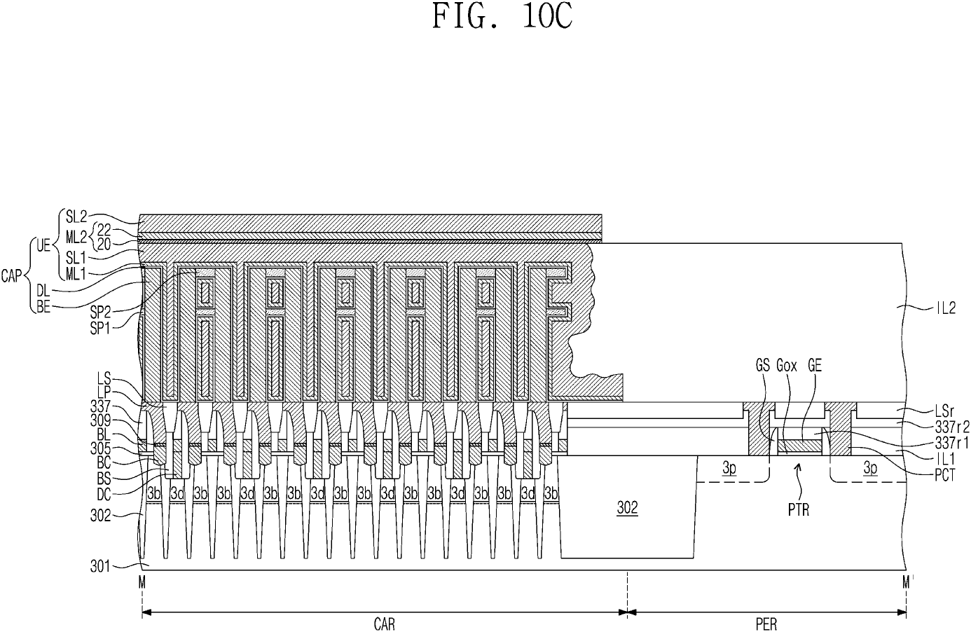

FIGS. 10A to 10C illustrate cross-sectional views showing a method of fabricating the semiconductor memory device of FIG. 9.

Referring to FIG. 10A, a dielectric layer DL, a first metal layer ML1, and a silicon-germanium layer SL1 may be sequentially stacked on an entire surface of the semiconductor substrate 301 in a state of FIG. 4A. While the silicon-germanium layer SL1 is formed, the silicon-germanium layer SL1 may be in-situ doped with first dopants (e.g., boron). A mask pattern MK may be formed on the silicon-germanium layer SL1. The mask pattern MK may be formed to cover top and lateral surfaces of the silicon-germanium layer SL1. The mask pattern MK may be, for example, a photoresist pattern or a spin-on-hardmask (SOH) pattern. The mask pattern MK may cover the cell array region CAR and expose the peripheral region PER. The mask pattern MK may be used as an etching mask to remove the dielectric layer DL, the first metal layer ML1, and the silicon-germanium layer SL1 from the peripheral region PER, such that the second dielectric layer LSr may be exposed.

Referring to FIG. 10B, the mask pattern MK may be removed to expose the top and lateral surfaces of the silicon-germanium layer SL1. The mask pattern MK may be removed by employing an ashing process that uses oxygen. In this step, the silicon-germanium layer SL1 may serve as a protection mask for prevention of oxidation of the first metal layer ML1. When the silicon-germanium layer SL1 is absent, oxygen may oxidize the first metal layer ML1 into metal oxide to remarkably increase an electrical resistance, and the top electrode UE may thus be difficult to act as an electrode. A second interlayer dielectric layer IL2 may be formed on the entire surface of the semiconductor substrate 301, covering the silicon-germanium layer SL1.

Referring to FIG. 10C, the second interlayer dielectric layer IL2 may undergo a polishing process such as chemical mechanical polishing (CMP). The polishing process may expose the top surface of the silicon-germanium layer SL1. In this step, the silicon-germanium layer SL1 may serve as a CMP stop layer. As the silicon-germanium layer SL1 serves as a CMP stop layer, the first metal layer ML1 may not be exposed. Therefore, a CMP apparatus may not be contaminated with metal included in the first metal layer ML1. The polishing process may allow the top surface of the silicon-germanium layer SL1 to become flat as illustrated in FIG. 9. The second interlayer dielectric layer IL2 may remain to cover the peripheral region PER, e.g., after the polishing process.

A second metal layer ML2 and a silicon layer SL2 may be sequentially stacked on the silicon-germanium layer SL1 and the second interlayer dielectric layer IL2, and then an etching process may be performed to remove the second metal layer ML2 and the silicon layer SL2 from the peripheral region PER and to expose a top surface of the second interlayer dielectric layer IL2. The second metal layer ML2 and the silicon layer SL2 may remain on the cell array region CAR, and a top electrode UE may be constituted by the first metal layer Ml1, the silicon-germanium layer SL1, the second metal layer ML2, and the silicon layer SL2.

Referring to FIG. 9, a third interlayer dielectric layer IL3 may be stacked on the silicon layer SL2 and the second interlayer dielectric layer IL2. The processes discussed above may be subsequently performed to fabricate the semiconductor memory device of FIG. 9.

In the present embodiment, the step of etching the first metal layer ML1 and the silicon-germanium layer SL1 may be different from the step of etching the second metal layer ML2 and the silicon layer SL2. For example, the first metal layer ML 1 and the silicon-germanium layer SL1 may be formed a photolithography process different from the photolithography process forming the second metal layer ML2 and the silicon layer SL2 as discussed above. Therefore, a mask pattern for etching the first metal layer ML1 and the silicon-germanium layer SL1 and a mask pattern for etching the second metal layer ML2 and the silicon layer SL2 may be formed at different steps from each other. Accordingly, the first metal layer ML1 and the silicon-germanium layer SL1 may have their sidewalls that are not vertically overlap or aligned with those of the second metal layer ML2 and the silicon layer SL2.

As the silicon-germanium layer SL1 has a flat top surface, the second metal layer ML2 and the silicon layer SL2 may also be formed to each have a flat top surface. Therefore, when forming cell contact holes CTH for cell contact plugs MC2, the cell contact holes CTH may be formed to have their uniform depth. Accordingly, the present embodiment may be beneficial to fabricate a semiconductor memory device capable of preventing process defects and increasing reliability. As shown in FIG. 9, the cell contact plug MC2 may have a bottom surface in contact with the second metal layer ML2 (e.g., the second sub-metal layer 22). The cell contact plug MC2 may have a lower sidewall in contact with the silicon layer SL2.

A semiconductor memory device according to some embodiments of the present inventive concepts may include a top electrode including a first metal layer, a silicon-germanium layer, a second metal layer, and a silicon layer that are sequentially stacked. Such configuration may decrease an absolute amount of boron in the top electrode, and thus air defects may be reduced or prevented. In addition, such configuration may reduce or prevent warpage of the semiconductor memory device. The silicon layer of the top electrode may include hydrogen atoms to improve refresh characteristics during operation of the semiconductor memory device. The top electrode may include a conductive adhesion layer to minimize or prevention delamination of the second metal layer. In addition, the top electrode may have a flat top surface to decrease a variation in depth when forming cell contact holes for cell contact plugs. As a result, present disclosure may be beneficial to provide a semiconductor memory device with increased reliability.

In a method of fabricating a semiconductor memory device according to some embodiments of the present inventive concepts, in an ashing process, the silicon layer and/or the silicon-germanium layer of the top electrode may serve to protect the second metal layer and/or the first metal layer. Therefore, there may be prevented the oxidation of the second metal layer and/or the first metal layer. Moreover, the silicon layer and/or the silicon-germanium layer of the top electrode may serve as a CMP stop layer to prevent contamination of CMP facility/equipment. Furthermore, a CMP process may be performed to allow the top electrode to have a flat top surface. When forming cell contact holes for cell contact plugs, the flat top surface of the top electrode may be beneficial to reduce a variation in depth which may be beneficial to prevent process defects and to increase a yield.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts. The embodiments of the FIG. 1 to 10C may be combined with each other.

1. A semiconductor memory device, comprising:
a semiconductor substrate that includes a cell array region and a peripheral region;
a plurality of bottom electrodes on the semiconductor substrate on the cell array region;
a dielectric layer that conformally covers sidewalls and top surfaces of the bottom electrodes; and
a top electrode on the dielectric layer and between the bottom electrodes,
wherein the top electrode includes a first metal layer, a silicon-germanium layer, a second metal layer, and a silicon layer that are sequentially stacked, and
wherein an amount of boron in the silicon-germanium layer is greater than an amount of boron in the silicon layer.

2. The device of claim 1, wherein a surface roughness at a top surface of the silicon layer is less than a surface roughness at a lateral surface of the silicon layer.

3. The device of claim 1, wherein the second metal layer includes a conductive adhesion layer facing the silicon-germanium layer.

4. The device of claim 3, wherein the conductive adhesion layer is formed of titanium.

5. The device of claim 1, further comprising:
an interlayer dielectric layer that covers the top electrode; and
a first contact plug that penetrates the interlayer dielectric layer to contact the top electrode,
wherein a bottom surface of the first contact plug is in contact with the second metal layer, and
wherein the silicon layer does not include boron.

6. The device of claim 5, further comprising an ohmic pattern between the silicon layer and a lateral surface of the first contact plug.

7. The device of claim 1, further comprising:
an interlayer dielectric layer that covers a top surface of the top electrode; and
a first contact plug that penetrates the interlayer dielectric layer to contact the top electrode,
wherein a bottom surface of the first contact plug is in the silicon layer, and
wherein the silicon layer includes boron.

8. The device of claim 7, further comprising an ohmic pattern between the silicon layer and the bottom surface of the first contact plug.

9. The device of claim 1, wherein lower sidewalls of the first metal layer, the silicon-germanium layer, the second metal layer, and the silicon layer are vertically aligned with each other adjacent to a boundary between the cell array region and the peripheral region.

10. The device of claim 1, further comprising an interlayer dielectric layer that covers a lateral surface of the top electrode,
wherein an upper sidewall of the second metal layer contacts the interlayer dielectric layer in an area adjacent to a boundary between the cell array region and the peripheral region.

11. The device of claim 1, wherein the second metal layer and the silicon layer expose a lateral surface of the silicon-germanium layer.

12. The device of claim 1, wherein lateral surfaces of the second metal layer and the silicon layer does not vertically overlap lateral surfaces of the first metal layer and the silicon-germanium layer.

13. A semiconductor memory device, comprising:
a semiconductor substrate that includes a cell array region and a peripheral region;
a plurality of bottom electrodes on the semiconductor substrate on the cell array region;
a dielectric layer that conformally covers sidewalls and top surfaces of the bottom electrodes; and
a top electrode on the dielectric layer and between the bottom electrodes,
wherein the top electrode includes a first metal layer, a silicon-germanium layer, a conductive adhesion layer, a second metal layer, and a silicon layer that are sequentially stacked.

14. The device of claim 13, wherein an amount of boron in the silicon-germanium layer is greater than an amount of boron in the silicon layer.

15. The device of claim 13, further comprising:
an interlayer dielectric layer that covers the top electrode; and
a first contact plug that penetrates the interlayer dielectric layer to contact the top electrode,
wherein a bottom surface of the first contact plug is in contact with the second metal layer, and
wherein the silicon layer does not include boron.

16. A semiconductor memory device, comprising:
a semiconductor substrate that includes a cell array region and a peripheral region;
a word line in the semiconductor substrate on the cell array region;
a first impurity region in the semiconductor substrate on one side of the word line;
a second impurity region in the semiconductor substrate on another side of the word line;
a bit line disposed on the semiconductor substrate on the cell array region and connected to the first impurity region, the bit line crossing over the word line;
a bottom electrode disposed on the semiconductor substrate on the cell array region and connected to the second impurity region;
a dielectric layer that conformally covers a sidewall and a top surface of the bottom electrode; and
a top electrode on the dielectric layer,
wherein the top electrode includes a first metal layer, a silicon-germanium layer, a second metal layer, and a silicon layer that are sequentially stacked,
wherein a surface roughness at a top surface of the silicon layer is equal to or less than about 10 nm root mean square (RMS), and
wherein a surface roughness at a lateral surface of the silicon layer is greater than about 10 nm root mean square (RMS) and equal to or less than about 1,000 nm root mean square (RMS).

17. The device of claim 16, wherein an amount of boron in the silicon-germanium layer is greater than an amount of boron in the silicon layer.

18. The device of claim 16, further comprising:
an interlayer dielectric layer that covers the top electrode; and
a first contact plug that penetrates the interlayer dielectric layer to contact the top electrode,
wherein a bottom surface of the first contact plug is in contact with the second metal layer, and
wherein the silicon layer does not include boron.

19. The device of claim 16, wherein the top electrode further includes a conductive adhesion layer between the silicon-germanium layer and the second metal layer.

20. The device of claim 16, wherein lateral surfaces of the second metal layer and the silicon layer are not aligned with lateral surfaces of the first metal layer and the silicon-germanium layer.

21-26. (canceled)
